(19) United States
(12) Patent Application Publication
(10) Pub. No.: US 2015/0171124 A1
(43) Pub. Date: Jun. 18, 2015

(54) ARCHITECTURE FOR PROVIDING PITCH VARIATION ACROSS A WAVEGUIDE BUNDLE FOR A PHOTODETECTOR ARRAY

(71) Applicant: Google Inc., Mountain View, CA (US)

(72) Inventors: Alessandro Temil, Campbell, CA (US); Roman Lewkow, San Jose, CA (US)

(73) Assignee: Google Inc., Mountain View, CA (US)

(21) Appl. No.: 14/109,609

(22) Filed: Dec. 17, 2013

(51) Int. Cl. H01L 27/146

(52) U.S. Cl. CPC H01L 27/14625; H01L 27/14685

(57) ABSTRACT

An image sensor device including a waveguide bundle coupled to a photodetector array. In an embodiment, the waveguide includes a first interface to receive light and a second interface to output such light to a photodetector array. The first interface includes a first array of waveguide ends, and the second interface includes a second array of waveguide ends. In another embodiment, a pitch of the first array is different than a pitch of the second array.

### BACKGROUND

1. Technical Field

This disclosure relates generally to the field of optics, and in particular but not exclusively, relates to the direction of light to a photodetector array.

2. Background Art

Current active pixel image sensors rely on focusing the image of a scene onto a planar array of photosensitive semiconductor material. In such image sensors, the geometry of an optical assembly (lenses) and device form factor requirements typically constrain the size of the focal plane. This in turn greatly constrains the physical size of each detector pixel of the image sensor, which—given a particular resolution requirement—has a direct impact on the complexity of the detector pixels that can be achieved within such constrained size.

The limited space available for each detector pixel dictates that current implementations of active pixel image sensors greatly sacrifice the achievable dynamic range, linearity and uniformity of response, and other parameters in order to fit in the physical size constraints arising from the factors mentioned above. The continued scaling provided by successive improvements in very-large-scale integration (VLSI) processes helps in terms of number of digital features that can be fit into a given area (e.g. square mm) of silicon wafer. However, analog features do not tend to scale with such digital process shrinkage, reducing the overall benefit for image sensor pixel designers.

Also, relatively sophisticated pixel designs like those including photo gate arrays and direct light-to-frequency converters are hard to realize given that any additional complexity in detector circuitry tends to limit or otherwise impact the available photodetector area, making the resulting sensor have comparatively poor performance. Consequently, there is an increasing desire for architectures to avail of advances in technologies for image sensor signal processing, control, etc., without sacrificing the semiconductor area of active photodetector elements.

### BRIEF DESCRIPTION OF THE DRAWINGS

The various embodiments of the present invention are illustrated by way of example, and not by way of limitation, in the figures of the accompanying drawings and in which:

FIG. 1 is a block diagram illustrating elements of a system for sensing an image according to an embodiment.

FIGS. 2A-2F are isometric diagrams illustrating elements image sensor devices according to respective embodiments.

FIG. 3 is a flow diagram illustrating elements of a method for fabricating an image sensor device according to an embodiment.

FIG. 4 is a top view of a near-to-eye imaging system to perform image sensing according to an embodiment.

### DETAILED DESCRIPTION

Embodiments discussed herein variously provide for waveguide structures to direct light to photodetectors for capturing an image. A waveguide bundle according to one embodiment includes a first interface to receive light and a second interface to output such light to a photodetector array. The first interface may include a first array of waveguide ends, and the second interface may include a second array of waveguide ends. In an embodiment, a pitch of the first array is different than a pitch of the second array. The difference between respective pitches (or, for brevity, “pitch differential”) of such interfaces may allow for additional spacing between photosensitive elements of the photodetector array.

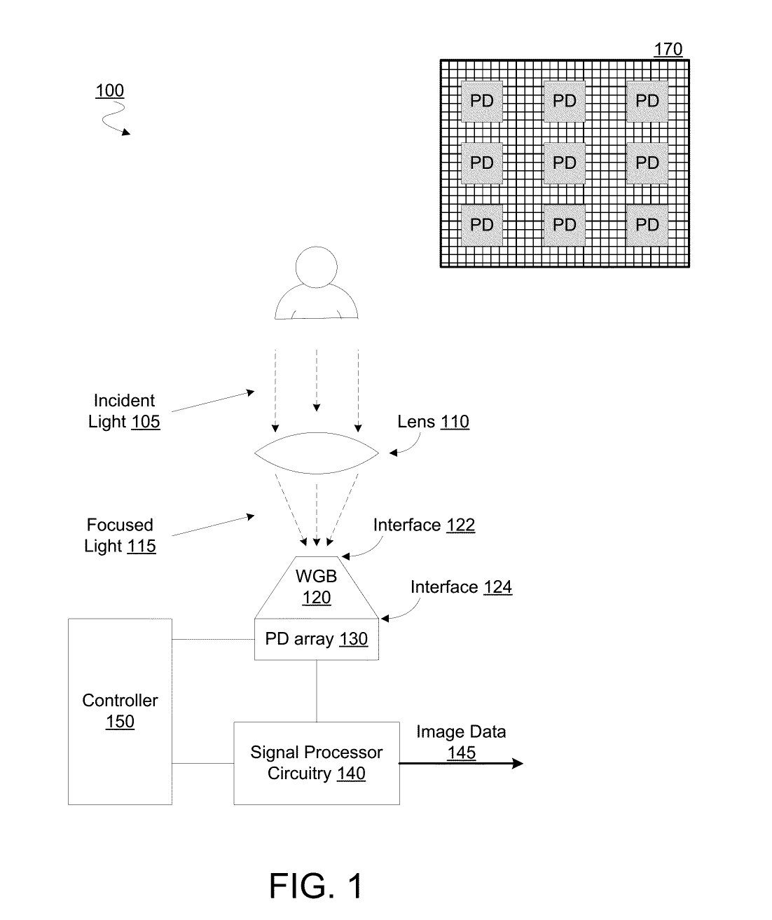

FIG. 1 is a functional block diagram illustrating a system 100 for capturing an image in accordance with an embodiment. System 100 may be or include any of a variety of consumer electronic devices (or a component thereof) including, but not limited to, a camcorder, laptop computer, desktop computer, handheld device (e.g. palmtop computer, smart phone, personal digital assistant, etc.), wearable device (e.g. near-eye display device), gaming console, television and/or the like. The illustrated embodiment of system 100 may include an optical assembly (as represented by the illustrative lens 110), a waveguide bundle WGB 120, a photodetector (PD) array 130, signal processor circuitry 140 and a controller 150.

During operation of system 100, lens 110 may receive incident light 105 from an environment which system 100 is to image. Lens 110 may provide focusing of the received incident light 105 into focused light 115. For example, lens 110 may variously direct focused light 115 toward a focal point, where an interface 122 of WGB 120 is located at or near the focal point to receive focused light 115.

WGB 120 may include a plurality of individual waveguides (not shown) which variously direct some or all of focused light 115 from interface 122 to another interface 124 of WGB 120. For example, each waveguide of the plurality of waveguides may include ends which are incorporated each into a respective one of interfaces 122, 124. In an embodiment, portions of the received focused light 15 are variously directed at least in part by total internal reflection within respective ones of the waveguides comprising WGB 120.

Such portions of light directed from interface 112 through WGB 120 may variously exit the plurality of waveguides via interface 124, where PD array 130 is coupled via interface 124 to receive such light from WGB 120. PD array 130 may include photo-sensitive elements (e.g., CMOS image sensors, photo-diodes, charged coupled devices, etc.) for generating signals representing an image from incident light 105. Such signals may be processed for acquiring low or high resolution still pictures/video pictures of an environment imaged thereby. In various embodiments, PD array 130 may generate signals for either or both of a still picture and a continuous video stream. Such photo-sensitive elements may include structures adapted from any of a variety of conventional photodetector architectures. By way of illustration and not limitation, PD array 215 may use CMOS photodiodes (e.g. P-N photodiode), but other technologies may be used. PD array 130 may be configured for frontside-illumination or backside illumination, according to various embodiments.

Interface 124 may include respective second ends of waveguides, where such second ends are each coupled to a different respective photodiode or other such photosensor element of PD array 130. For example, waveguide ends may each be coupled to a semiconductor substrate (such as that of an integrated circuit chip) on which, or in which, is disposed (e.g. doped) a corresponding photosensor element, where the waveguide end is aligned to direct light toward that corresponding photosensor element.

PD array 130 may couple to or include—e.g. may be disposed in or on the same semiconductor die or silicon substrate as—one of more signal lines, transistors, supply voltage traces, ground potential traces and/or other structures which support the operation of photodiodes of PD array 130 and/or the processing of signals provided by such photodiodes. Alternatively or in addition, some or all such structures may be incorporated into signal processor circuitry 140 and/or controller 150.

In an embodiment, signal processor circuitry 140 includes circuitry to perform digital signal processing for signals received from PD array 140. Operation of PD array and/or signal processor circuitry 140 may be directed by signaling from controller 150. For example, controller 150 may coordinate exposure timing, charging/discharging of photodiodes, bitline readout timing and/or other functionality. Processing operations of signal processor 140 and/or control operations of controller 150 may each include respective operations adapted from conventional techniques for operating an image sensor pixel array, which may vary widely according to implementation-specific details and which are not limiting on certain embodiments.

Controller 150 may be implemented as a processor, an application specific integrated circuit (“ASIC”), a field programmable gate array (“FPGA”), a general purpose processor executing firmware/software instructions, or otherwise. Executable instructions may be stored in a memory unit (not shown) included in or coupled to controller 150. Alternatively, the instructions executed by controller 150 may be hardwired logic. In an embodiment, signal processor circuitry 140 performs operations to arrange, filter, schedule or otherwise condition signals generated by from PD array 130. Image data 145 resulting from such operations may be provided, for example, to one or more elements (not shown) included in or coupled to system 100 such as a memory, a display, a wired or wireless network interface, or the like.

Detail view 170 shows an illustrative distribution of active photosensitive elements (in this example, photodiodes) in an array such as PD array 130. More particularly, boxes PD in detail view 170 illustrate photodiode regions arranged in an array, where such regions are separated from other another by other regions in which may be located, for example, semiconductor, metal layer and/or other circuit structures—such as bitlines, supply voltage traces, groundline traces, transistors, etc.—which are included in, shared by, or otherwise to provide for operation of image sensor pixel cells. Embodiments discussed herein variously provide for tight focusing of light for image sensing, without also requiring close proximity (and/or small size) for photodetectors which are to participate in such image sensing. Accordingly, such embodiments allow for improved PD array circuitry for signal communication, processing etc. while at the same time allowing semiconductor real estate to retain or increase a total area dedicated to photosensitive elements of the PD array.

For example, waveguide ends of interface 122 may be arranged with respect to one another in a first array, and waveguide ends of interface 124 may be similarly arranged with respect to one another in a second array. In an embodiment, such a first array and second array may be characterized each by a different respective pitch. As used herein with respect to a given array, “pitch” refers to a distance between the same corresponding points of different adjacent elements in that array. For example, pitch may be measured from a corner, side, middle or other reference point of an array element, provided the measure is also to a corresponding corner, side, middle or other congruent reference point of an adjoining array element.

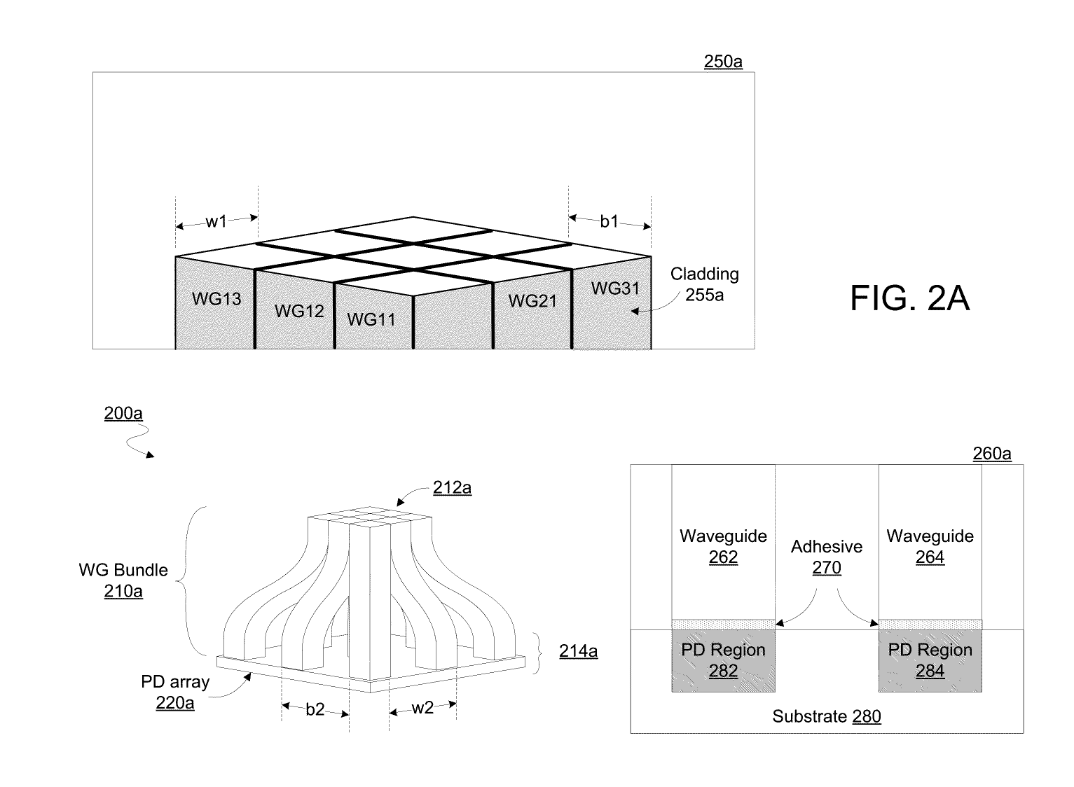

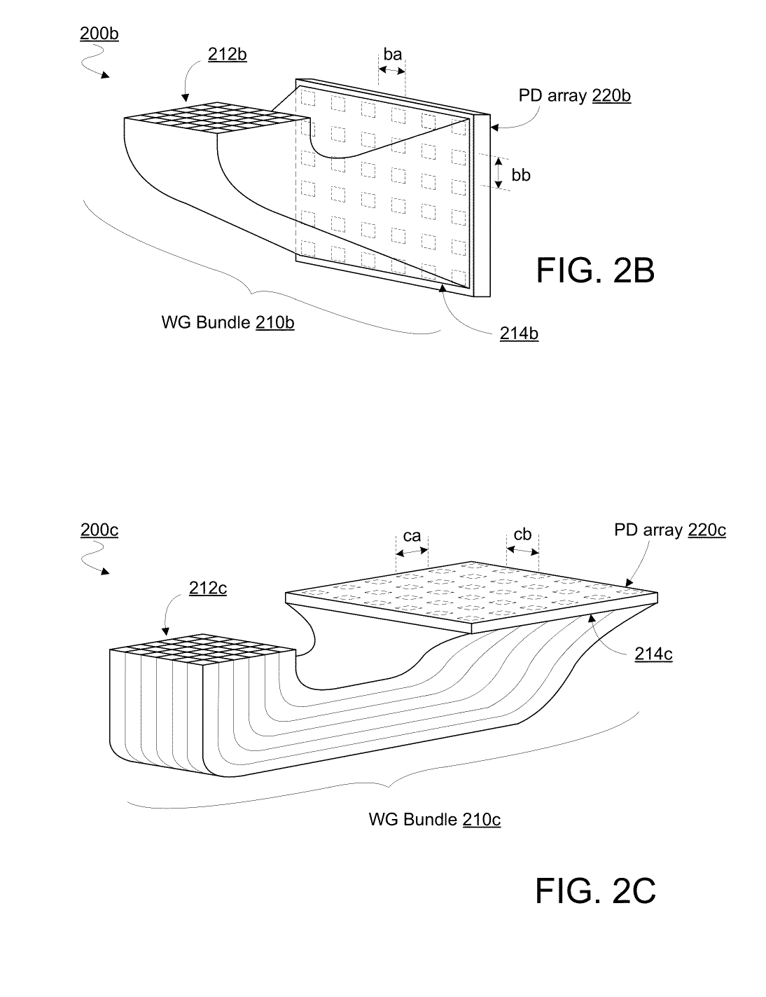

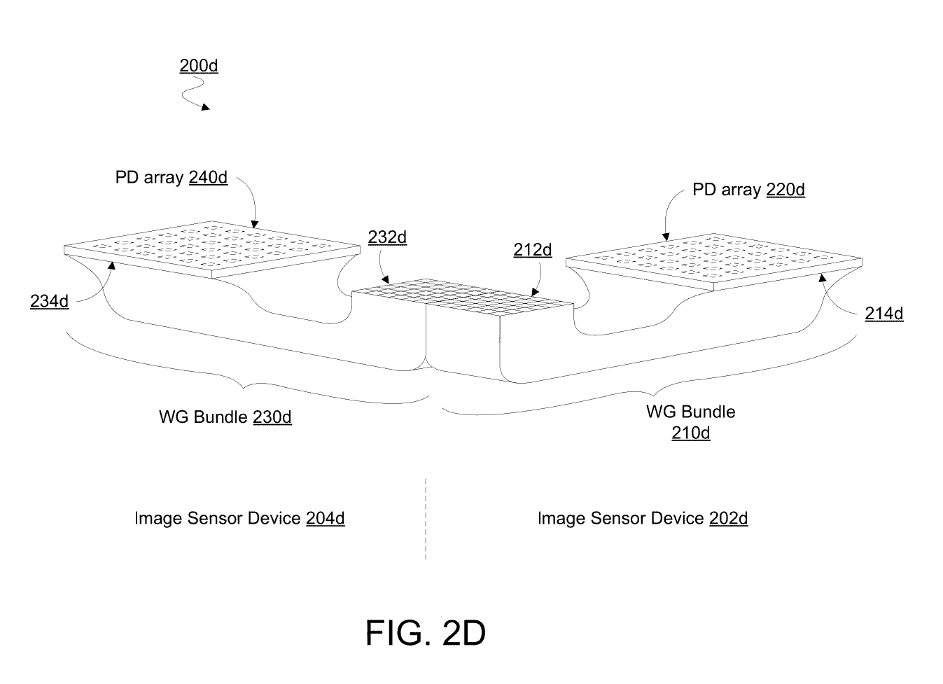

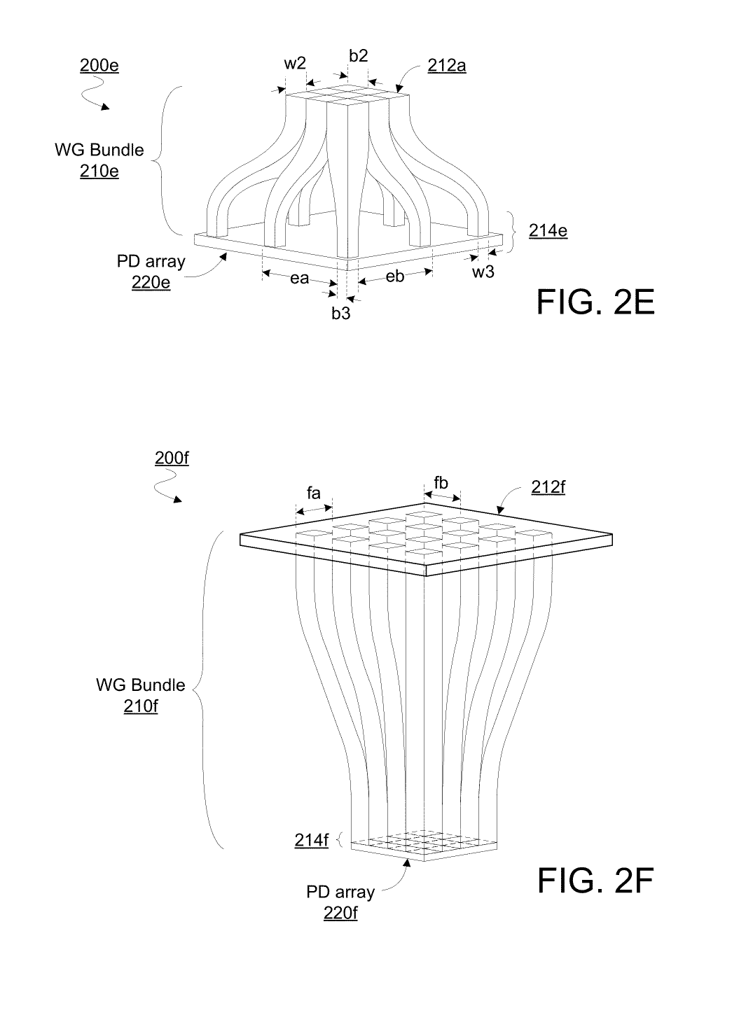

As discussed herein with reference to FIGS. 2A through 2F, certain embodiments variously provide for a waveguide bundle to have two interfaces each comprising a respective array of waveguide ends, where one of the arrays has a pitch corresponding to a pitch of a PD array such as that shown in detail view 170. The other array of such a waveguide bundle may have a different pitch—e.g. where waveguide ends of the other array are each adjacent to another waveguide end of the other array.

FIG. 2A shows elements of an image sensor 200a for generating signals representing image information according to an embodiment. Device 200a may include some or all of the features of system 100. For example, image sensor 200a may include a waveguide bundle 210a and photodetector (PD) array 220a which provide some or all of the respective functionality of WGB 120 and PD array 130.

In an embodiment, waveguide bundle 210a includes a plurality of waveguides each to receive, via a first interface 212a, respective light which is then directed to and output from a second interface 214a of waveguide bundle 210a coupled to PD array 220a. As shown in a detail view 250a, first interface 212a may include respective first ends of the plurality of waveguides—e.g. where such first ends are arranged in a first array having a first pitch. By way of illustration and not limitation, the plurality of waveguides may include waveguides WG11, WG12, WG13, WG21, WG31, where respective first ends of WG11, WG12, WG13 are arranged in a row (or column) of the first array, and where respective ends of WG11, WG21, WG31 are arranged in a column (or row) of the first array.

By contrast, second interface 214a may include respective second ends of the plurality of waveguides—e.g. where such second ends are arranged in a second array having a second pitch which is different than the first pitch. Arrangement of such a second array may correspond to (e.g. align with) an arrangement of photodiodes (or other active photosensor elements) of PD array 220a. As shown in a detail view 260a, the plurality of waveguides may each be aligned with and coupled to a different respective photodetector of PD array 210a. For example, waveguide bundle 210a may include waveguides 262, 264 which are coupled to direct light toward respective doped PD regions 282, 284 in a semiconductor substrate 280 of PD array 220a. The respective second ends of waveguides 262, 264 may be coupled directly or indirectly to PD regions 282, 284, respectively—e.g. via adhesive 270 which has an index of refraction substantially equal to (e.g., ±5%) that of an optically transmissive material of waveguides 262, 264. In an embodiment, waveguides 262, 264 couple to respective PD regions 282, 284 via a metal stack and/or other structures (not shown) of PD array 220a.

The plurality of waveguides may each include a respective core of optically transmissive material such as any of various glass and/or plastic materials adapted from conventional fiberoptic applications. By way of illustration and not limitation, some or all waveguides of waveguide bundle 210a may comprise cores of plastic optical fiber (POF), poly(methyl methacrylate) (PMMA) and/or the like. The respective cores of such waveguides may be separated from one another by a cladding material 255a which is variously disposed around and/or between such cores. Cladding 225a may include any of a variety of materials which provide for total internal reflection within the wave guide cores. Such total internal reflection may be achieved, for example, by selecting a material for cladding 225a which has an index of refraction which is different from that of a waveguide core—e.g., according to criteria adapted from conventional fiberoptic techniques.

In an embodiment, respective portions of one or more fiberoptic cores may adjoin air or some other gas which serves as cladding between cores. A difference between respective indices of refraction of a core and such an adjoining gas may provide for total internal reflection within the core at an interface with the gas. Image sensor 200a may include additional structures (not shown) to provide rigid support for waveguide bundle 210a. By way of illustration and not limitation, waveguide bundle 210a may be disposed or otherwise formed within an integrated circuit package material, although certain embodiments are not limited in this regard. In an embodiment, curvature of a waveguide to facilitate a pitch differential is gradual enough to facilitate internal reflection of an optical signal within that waveguide.

First interface 212a may include any of a variety of arrays of waveguide ends which are alternative to, or in addition to, the 3×3 array shown in detail view 250a. Although the waveguide ends of first interface 212a are shown as rectangular (e.g. square), certain embodiments are not limited in this regard. For example, some or all such waveguide ends may include edges having a circular, elliptical or other geometric shape. The first pitch of first interface 212a may be measured, for example, based on a distance w1 along a first dimension between corresponding points (e.g. sides, corners, centers) of adjacent waveguide ends. Alternatively or in addition, the first pitch may be measured based on a distance b1 along another dimension between corresponding points of adjacent waveguide ends. Distances w1, b1 may be equal to each other, for example. By contrast, the second pitch of first interface 214a may be measured, for example, based on a distance w2 other than w1 and/or a distance b2 other than b1. In an illustrative scenario according to one embodiment, w1 (and/or b1) is equal to 2 microns and w2 (and/or b2) is equal to 4 microns. However, any of a variety of additional or alternative pitches for interfaces 212a, 214a may be provided, according to different embodiments.

In FIG. 2A, the respective first ends and second ends of interfaces 212a, 214a are shown as being flat—e.g. where such waveguide ends are polished during fabrication and/or assembly. However, in another embodiment, some or all such waveguide ends may be variously textured or otherwise shaped. For example, waveguide ends may be selectively etched to be concave, convex or otherwise curved. Alternatively or in addition, waveguide ends may be shaped each to include surface portions which are angled with respect to one another. Such shaping of waveguide ends may improve a focusing of light from a waveguide into a corresponding photodetector. Alternatively or in addition, such shaping of waveguide ends may improve the collection of light which is obliquely incident upon a waveguide interface.

Although image sensor 200a is shown as including a PD array 220a which is disposed directly in line with and facing first interface 212a, certain embodiments are not limited in this regard. For example, FIG. 2B shows elements of an image sensor 200b according to an alternate embodiment. Device 200b includes a waveguide bundle 210b and photodetector (PD) array 220b which, for example, provide some or all of the respective functionality of WGB 120 and PD array 130.

In an embodiment, waveguide bundle 210b includes a first interface 212b to receive light which is then directed to and output from a second interface 214b of waveguide bundle 210b. Second interface 214b may be coupled to PD array 220b—e.g. where waveguide bundle 210b includes the last optically transmissive material to variously direct such light onto PD array 220b. First interface 212b may include a first array of waveguide ends—e.g. where the first array is characterized by a first pitch. By contrast, second interface 214b may include a second array of waveguide ends, where a second pitch of the second array is different (in this example greater) than the first pitch.

By way of illustration and not limitation, the second pitch may be characterized by a distance ba along a row (or column) dimension for PD array 220b and/or by a distance bb along a column (or row) dimension for PD array 220b. In an illustrative scenario according to one embodiment, the first pitch of first interface 212b is in a range of 1-4 microns and the second pitch is at least 2× the first pitch. However, such illustrative pitch values may vary widely according to implementation-specific details, and are not limiting on certain embodiments.

Typically, a total area of first interface 212a may be on the order of up to millions of square microns. Additionally or alternatively, a length of waveguide bundle 210a between interfaces 212a, 214a may be on the order of hundreds of microns—e.g. up to one 1 mm. However, certain embodiments are not limited with respect to a total area of a first interface, a total area of a second interface and/or a length of a waveguide bundle between such interface.

As shown in FIG. 2B, waveguide bundle 210b may be fabricated, shaped or otherwise formed to have one or more bends—e.g. in addition to any bends which are to provide a pitch differential between interfaces 212b, 214b—to accommodate PD array 220b being in a position other than directly under and/or facing first interface 212b. In the illustrative embodiment of image sensor 200b, waveguide bundle 210b may include a curving “L shape” bend to accommodate PD array 220b facing a direction which is not parallel (e.g. is orthogonal) to a direction faced by first interface 212b.

FIG. 2C shows elements of an image sensor 200c including another example of a curved waveguide bundle according to an alternate embodiment. Device 200c includes a waveguide bundle 210c and photodetector (PD) array 220c which, for example, provide some or all of the respective functionality of waveguide bundle 210b and PD array 220b.

In an embodiment, waveguide bundle 210c includes a first interface 212c to receive light which is then directed to and output from a second interface 214c of waveguide bundle 210c to PD array 220c. Similar to interfaces 212a, 214a, for example, first interface 212c and second interface 214c may include respective arrays of waveguide ends, where the respective arrays have pitches which are different from one another. By way of illustration and not limitation, the pitch of second interface 214b may be characterized by a distance ca along a row (or column) of PD array 220c and/or by a distance cb along a column (or row) of PD array 220c. One or both of distances ca, cb may be larger (e.g. by a factor of at least two) than a pitch value for first interface 212b.

In an embodiment, waveguide bundle 210c may be fabricated, shaped or otherwise formed to have multiple bends—e.g. to form the illustrative curving “U shape” shown. Such bends may, for example, accommodate PD array 220c facing a direction which is opposite to and/or offset from a direction faced by first interface 212c.

In an embodiment, a bend or bends in a waveguide bundle—e.g. the L-shaped bend of waveguide bundle 210b or the U-shaped bends of waveguide bundle 210c—may facilitate compliance with physical constraints of a given use case. Additionally or alternatively, bending of a waveguide bundle may allow for isolation of a PD array from radiation. For example, one embodiment may include a scintillator film material disposed on some or all of an interface such as one of first interfaces 212b, 214b. In operation, such a material may be generate visible or other light in response to being exposed to ionizing or otherwise highly energized radiation. Such light may be carried by the waveguide bundle to a photodetector array which is protected from such radiation by lead or other shielding material.

FIG. 2D shows elements of a system 200d according to an embodiment which includes an assembly of multiple image sensor devices. Features of such a system are discussed herein with respect to an assembly of image sensor devices such as image sensor 200c. However, such discussion may be extended to apply to an assembly including any of a variety of additional or alternative image sensor devices.

System 200d includes a first image sensor device 202d comprising a PD array 220d and a waveguide bundle 210d coupled thereto. Waveguide bundle 210d may include a first interface 212d to receive light and a second interface 214d to variously direct such light to respective photodetector elements of PD array 220d. System 200d may further include a second image sensor device 204d comprising a PD array 240d and a waveguide bundle 230d coupled thereto. Waveguide bundle 230d may include a first interface 232d to receive light and a second interface 234d to variously direct such light to respective photodetector elements of PD array 240d.

In an embodiment, first image sensor device 202d and second image sensor device 204d receive respective portions of focused light—e.g. concurrently—and variously direct such respective portions to different ones of PD arrays 220d, 240d. In the illustrative embodiment of system 200d, waveguide bundles 210d, 230d may direct light away from interfaces 212d, 232d along different lines of direction—e.g. directions which are orthogonal to one another. However, in other embodiments, an assembly may additionally or alternatively include waveguide bundles which each direct respective light along parallel lines of direction.

FIG. 2E shows elements of an image sensor 200e including an example of a curved and tapered waveguide bundle according to another embodiment. Device 200e includes a waveguide bundle 210e and PD array 220e coupled thereto, wherein waveguide bundle 210e includes a first interface 212e to receive light which is then directed to and output from a second interface 214e of waveguide bundle 210e to PD array 220e.

A pitch of a first array of first interface 212a may be characterized by a distance w2 along a row (or column) of the first array and/or by a distance b2 along a column (or row) of the first array. By contrast, a pitch of a second array of second interface 214a may be characterized by a distance eb along a row (or column) of the second array and/or by a distance ea along a column (or row) of the second array.

Additionally or alternatively, some or all waveguides of waveguide bundle 210e may variously taper from comparatively large cross-sectional areas to comparatively small cross-sectional areas (or vice-versa) along the length of waveguide bundle 210e. By way of illustration and not limitation, waveguides may taper from width w2 at first interface 212a to width w3 at second interface 214e. Additionally or alternatively, waveguides may taper from breadth b2 at first interface 212a to breadth b3 at second interface 214e.

FIG. 2F shows elements of an image sensor 200f which provides for a pitch differential across a waveguide bundle according to another embodiment. Device 200f includes a waveguide bundle 210f and PD array 220f coupled thereto, wherein waveguide bundle 210f includes a first interface 212f to receive light which is then directed to and output from a second interface 214f of waveguide bundle 210f to PD array 220f.

First interface 212f and second interface 214f may include, respectively, a first array of waveguide ends and a second array of waveguide ends. In the illustrative embodiment of image sensor 200f, the first array has a first pitch which is greater than a second pitch of the second array. For example, the first pitch may be characterized by a distance fa along a row (or column) of the first array and/or by a distance fb along a column (or row) of the first array. One or each of distances fa, fb may be greater than a width (and/or a breadth) of a waveguide of waveguide bundle 210f. By contrast, the second array may include waveguide ends which are adjacent to one another, or may otherwise have a pitch less than fa (and/or fb).

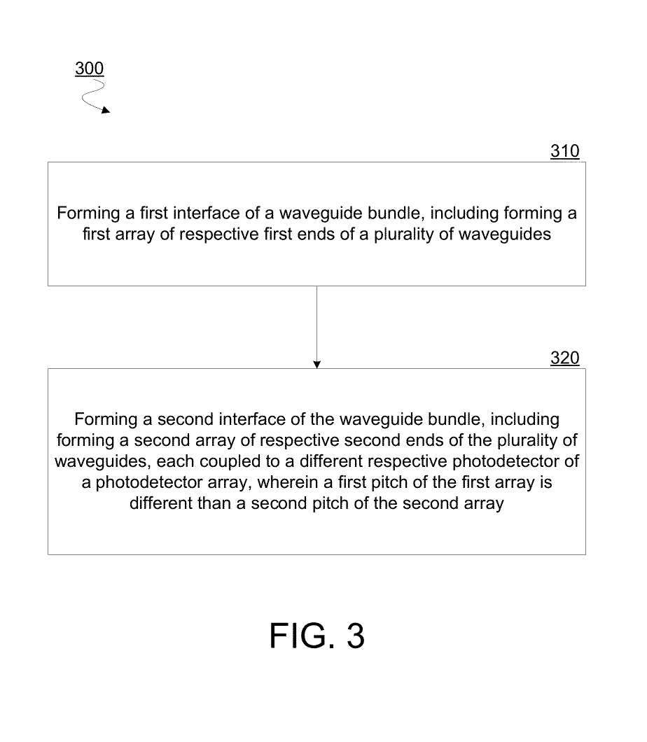

FIG. 3 illustrates elements of a method 300 for making an image sensor device according to an embodiment. Method 300 may fabricate, assemble or otherwise make a device having some or all of the features one of system 200d or one of image sensors 200a-200c, 200e, 200f, for example.

In an embodiment, method 300 includes, at 310, forming a first interface of a waveguide bundle including a plurality of waveguides. Each waveguide of the plurality of waveguides may include a respective first end and a respective second end. The forming the first interface at 310 may comprise forming a first array of the first ends of the plurality of waveguides. For example, the forming at 310 may include performing etch, mask and/or deposition operations—e.g. including one or more processes adapted from conventional micromachining and/or photonic integrated circuit fabrication techniques—to deposit optically transmissive material for individual waveguide structures, and in some embodiments, cladding material to optically separate or otherwise define such individual waveguide structures.

Method 300 may further comprise, at 320, forming a second interface of the waveguide bundle, wherein forming the second interface comprises forming a second array of the second ends. The respective second ends of the plurality of waveguides may each be coupled to a different respective photodetector of a photodetector array. For example, the forming at 320 may include adhering or otherwise bonding waveguides each to a semiconductor substrate on which or in which is disposed a corresponding photosensitive element. In an embodiment, a first pitch of the first array is different than a second pitch of the second array.

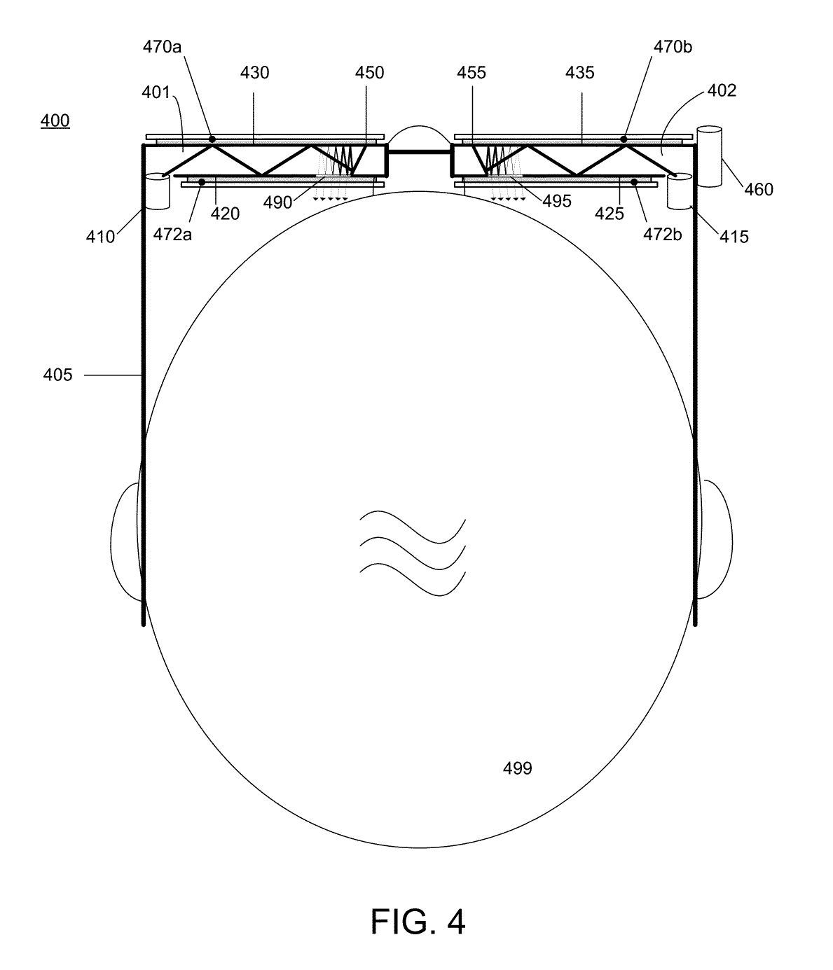

FIG. 4 is a top view of a demonstrative near-to-eye imaging system 400 in accordance with an embodiment. Imaging system 400 is merely one example, of an apparatus which includes image sensor mechanisms having feature such as those discussed herein. Any of a variety of other imaging systems may include such image sensor mechanisms, according to different embodiments.

The illustrated embodiment of imaging system 400 includes two image waveguides 401 and 402, frame 405 including a nose assembly, a left ear assembly, and a right ear assembly, and two image sources 410 and 415.

In this embodiment, image waveguides 401 and 402 are secured into an eye glass arrangement that can be worn on head 499 of a user. The left and right ear assemblies rest over the user's ears while the nose assembly rests over the user's nose. The frame assembly is shaped and sized to position out-coupling regions 490 and 495 of each image waveguide in front of a corresponding eye of the user with the emission surfaces facing the eyes.

Left and right (binocular) CGIs are generated by image sources 410 and 415, respectively. In one embodiment, image sources 410 and 415 each utilize an independent lamp source and a reflective display (e.g., liquid crystal on silicon (“LCoS”)). Of course, other display technologies may be used such as back lit LED displays, quantum dot arrays, organic LED displays, etc. The CGI output by image sources 410 and 415 is launched into their respective image waveguides, 401 and 402, guided through the intermediate regions of said waveguides via reflective parallel surfaces (420 and 430 for waveguide 401, 425 and 435 for waveguide 402), and emitted from out-coupling regions 490 and 495 near to the user's eyes. In other embodiments, a single image source may generate the above described left and right CGIs (e.g., the single image source may be placed near the nose assembly of frame 405, or signals from the single image source may be optically routed to the each of the user's eyes).

Waveguides 401 and 402 propagate light at a shallow angle, as described above. Although certain embodiments are not limited in this regard, the angle of the light may be increased so that it is closer to normal prior to exiting waveguides 401 and 402—e.g. due to reflective end surfaces 450 and 455, respectively. In one embodiment, image waveguides 401 and 402 emit substantially collimated CGI light and therefore virtually project the image at or near infinity. Although the human eye is typically incapable of bringing objects within a few centimeters into focus, since the output light is virtually displayed at or near infinity, the image is readily in focus.

Imaging system 400 may include one or more structures for protection of one or more surfaces of waveguides 401, 402. By way of illustration and not limitation, the opposing surfaces of waveguide 401 may each be protected by a respective one of encapsulation portions 470a, 472a. Similarly, the opposing surfaces of waveguide 401 may each be protected by a respective one of encapsulation portions 470b, 472b.

In an embodiment, imaging system 400 includes an image sensor 460 which, for example, is incorporated into or otherwise coupled to frame 405. Image sensor 460 may capture one or more images which, for example, may be uploaded from imaging system 400 via a wireless connection to a home network, Internet or the like. In an embodiment, image sensor 460 includes a waveguide bundle and a photodetector array coupled thereto. The waveguide bundle and photodetector array of image sensor 460 may include one or more features—such as those discussed herein—which, for example, facilitate improved size and/or utilization of active photosensitive elements of the photodetector array.

Techniques and architectures for performing photodetection are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. An image sensor comprising:
a first photodetector array including a first plurality of photodetectors;
a first waveguide bundle including a first plurality of waveguides, wherein each waveguide of the first plurality of waveguides includes a respective first end and a respective second end, wherein the first waveguide bundle includes:
a first interface to receive light, the first interface comprising a first array of the first ends of the first plurality of waveguides; and
a second interface to direct the light to the first photodetector array, the second interface comprising a second array of the second ends of the first plurality of waveguides, wherein the first plurality of photodetectors are each coupled to a different respective one of the second ends of the first plurality of waveguides, and wherein a first pitch of the first array is different than a second pitch of the second array.

2. The image sensor device of claim 1, wherein the second pitch is greater than the first pitch.

3. The image sensor device of claim 2, wherein the second pitch is at least twice the first pitch.

4. The image sensor device of claim 1, wherein the waveguide bundle forms one or more bends between the first interface and the second interface.

5. The image sensor device of claim 1, wherein the plurality of waveguides each taper between the first interface and the second interface.

6. The image sensor device of claim 1, wherein some or all of the plurality of waveguides each include a respective end surface which is curved or angled.

7. The image sensor device of claim 6, wherein some or all of the plurality of waveguides each include a respective end surface which is concave or convex.

8. The image sensor device of claim 1, wherein the respective second ends of the plurality of waveguides are adhered to the photodetector array.

9. The image sensor device of claim 1, further comprising:
a second photodetector array including a second plurality of photodetectors;
a second waveguide bundle including a second plurality of waveguides, wherein each waveguide of the second plurality of waveguides includes a respective third end and a respective fourth end, wherein the second waveguide bundle includes:
a third interface to receive light, the third interface comprising a third array of the third ends of the second plurality of waveguides, the third array adjacent to the first array; and
a fourth interface to direct the light to the second photodetector array, the fourth interface comprising a fourth array of the second ends of the fourth plurality of waveguides, wherein the second plurality of photodetectors are each coupled to a different respective one of the fourth ends of the second plurality of waveguides, and wherein a third pitch of the third array is different than a fourth pitch of the fourth array.

10. The image sensor device of claim 9, wherein the first waveguide bundle to direct first light in a first direction and the second waveguide bundle to direct second light in a second direction other than the first direction.

11. The image sensor device of claim 1, further comprising a film of scintillator material disposed on some or all of the first ends.

12. The image sensor device of claim 1, further comprising a shield to limit exposure of the photodetector array to radiation.

13. A system comprising:
an optical assembly to focus light to a focal point;
an image sensor comprising:
a first photodetector array including a first plurality of photodetectors;
a first waveguide bundle including a first plurality of waveguides, wherein each waveguide of the first plurality of waveguides includes a respective first end and a respective second end, wherein the first waveguide bundle includes:
a first interface to receive a first portion of the light, the first interface comprising a first array of the first ends of the first plurality of waveguides; and
a second interface to direct the light to the first photodetector array, the second interface comprising a second array of the second ends of the first plurality of waveguides, wherein the first plurality of photodetectors are each coupled to a different respective one of the second ends of the first plurality of waveguides, and wherein a first pitch of the first array is different than a second pitch of the second array;
a controller including circuit logic configured to generate control signaling for the first photodetector array to generate signals based on the light; and
signal processor circuitry to perform digital processing of the signals.

14. The system of claim 13, wherein the second pitch is greater than the first pitch.

15. The system of claim 13, wherein the waveguide bundle forms one or more bends between the first interface and the second interface.

16. The system of claim 13, wherein the plurality of waveguides each taper between the first interface and the second interface.

17. A method of fabricating an image sensor, the method comprising:
forming a first interface of a waveguide bundle including a plurality of waveguides, wherein each waveguide of the plurality of waveguides includes a respective first end and a respective second end, the forming the first interface comprising forming a first array of the first ends of the plurality of waveguides;
forming a second interface of the waveguide bundle, wherein forming the second interface comprises forming a second array of the second ends of the plurality of waveguides, wherein a first pitch of the first array is different than a second pitch of the second array, wherein the respective second ends of the plurality of waveguides are each coupled to a different respective photodetector of a photodetector array.

18. The method of claim 17, wherein the second pitch is greater than the first pitch.

19. The method of claim 17, further comprising forming one or more bends of the waveguide bundle between the first interface and the second interface.

20. The method of claim 17, wherein the plurality of waveguides each taper between the first interface and the second interface.
